(19) United States
(12) Patent Application Publication
(10) Pub. No.: US 2023/0303922 A1
(43) Pub. Date: Sep. 28, 2023

(54) FLUORESCENT MATERIAL

(71) Applicant: Sumitomo Chemical Company, Limited, Tokyo (JP)

(72) Inventors: Masaki KANNAMI, Tsukuba-shi, Ibaraki (JP); Kentaro IWASAKI, Niihama-shi, Ehime (JP); Shota NAITO, Tsukuba-shi, Ibaraki (JP); Shinichi SASAKI, Tsukuba-shi, Ibaraki (JP)

(21) Appl. No.: 18/015,546

(22) PCT Filed: Jul. 12, 2021
(86) PCT No.: PCT/JP2021/026084

§ 371 Date: Jan. 11, 2023

(30) Foreign Application Priority Data
Jul. 16, 2020 (JP) 2020-122208
Nov. 17, 2020 (JP) 2020-191193
Jul. 7, 2021 (JP) 2021-112513

(51) Int. Cl. C09K 11/64

(52) U.S. Cl. CPC C09K 11/64; H01L 33/50

(57) ABSTRACT

A fluorescent material has a core-shell structure. The core contains a crystal phase of an inorganic compound having Formula: MxMgaAlyOzNw (A); M represents a metal; × satisfies 0.001 ≤ × ≤ 0.3; a satisfies 0 ≤ a ≤ 1.0 - ×; y satisfies 1.2 ≤ y ≤ 11.3; z satisfies 2.8 ≤ z ≤ 18; and w satisfies 0 ≤ w ≤ 1.0. The shell is formed on at least a part of a surface of the core and contains boron and/or silicon. The core has a sodium content of 1700 ppm by mass or less and a specific surface area of 0.01 to 4.30 m²/g. A ratio Y/X of a peak area value Y of boron or silicon to a peak area value X of metal M present in the shell satisfies 0 < Y/X ≤ 0.095 in an EDX measurement of a cross section of the fluorescent material.

### TECHNICAL FIELD

The present invention relates to a fluorescent material, particularly a fluorescent material having excellent emission intensity.

### BACKGROUND ART

As a fluorescent material used for a white LED, Patent Document 1 discloses a fluorescent material doped with Mn and having a spinel-type structure represented by composition formulas: MgAl₂O₄ and MgGa₂O₄.

### PRIOR ART DOCUMENTS

### Patent Documents

Patent Document 1: JP-A-2016-17125

### SUMMARY OF THE INVENTION

### Problems to Be Solved by the Invention

A fluorescent material used in a light emitting device is required to have excellent emission intensity.

An object of the present invention is to provide a fluorescent material having excellent emission intensity.

### Means for Solving the Problems

The present invention provides a fluorescent material having a core-shell structure including a core part and a shell part,
the core part composed of a crystal phase of an inorganic compound having an elemental composition represented by Formula:

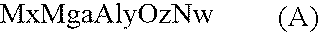

wherein: M represents at least one metal element selected from the group consisting of manganese, strontium, cerium, praseodymium, neodymium, samarium, europium, gadolinium, terbium, dysprosium, thulium, zinc, and ytterbium; x satisfies 0.001 ≤ × ≤ 0.3; a satisfies 0 ≤ a ≤ 1.0 - ×; y satisfies 1.2 ≤ y ≤ 11.3; z satisfies 2.8 ≤ z ≤ 18; and w satisfies 0 ≤ w ≤ 1.0,
the shell part formed on at least a part of a surface of the core part and containing at least one element selected from the group consisting of boron and silicon, wherein:
   the core part has a sodium content of 1700 ppm by mass or less and a specific surface area of 0.01 to 4.30 m²/g; and
   a ratio Y/X of a peak area value Y of boron or silicon to a peak area value X of the metal element M present in the shell part satisfies 0 < Y/X ≤ 0.095 when EDX measurement of a cross section of the fluorescent material is performed.

The present invention provides a fluorescent material represented by Formula:

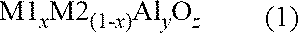

wherein: M1 and M2 represent one or more different metal elements; × satisfies 0.001 ≤ × ≤ 0.3; y satisfies 1.2 ≤ y ≤ 11.3; and z satisfies 2.8 ≤ z ≤ 18,
the fluorescent material having a sodium content of 1700 ppm by mass or less and a specific surface area of 0.01 to 4.30 m²/g.

In one embodiment, the fluorescent material has a spinel-type crystal structure.

In one embodiment, in the fluorescent material, the M1 is at least one metal element selected from the group consisting of manganese, cerium, praseodymium, neodymium, samarium, europium, gadolinium, terbium, dysprosium, thulium, and ytterbium, and the M2 is magnesium.

The present invention provides a fluorescent material represented by Formula:

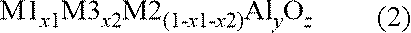

wherein: M1, M2, and M3 represent one or more different metal elements; ×1 and ×2 satisfy 0.012 ≤ ×1 + ×2 ≤ 0.14, and 1.4 ≤ ×1/×2 ≤ 1.8; y satisfies y = 2; and z satisfies z = 4,
the fluorescent material having a sodium content of 1700 ppm by mass or less and a specific surface area of 0.01 to 4.30 m²/g.

In one embodiment, the M1 is at least one metal element selected from the group consisting of manganese, cerium, praseodymium, neodymium, samarium, europium, gadolinium, terbium, dysprosium, thulium, and ytterbium; the M2 is magnesium; and the M3 is at least one metal element selected from the group consisting of zinc, cerium, praseodymium, neodymium, samarium, europium, gadolinium, terbium, dysprosium, thulium, and ytterbium.

The present invention also provides a film including any one of the fluorescent materials.

The present invention also provides a light emitting element including any one of the fluorescent materials.

The present invention also provides a light emitting device including the light emitting element.

The present invention also provides a display including the light emitting element.

The present invention also provides a phosphor wheel including any one of the fluorescent materials.

The present invention also provides a projector including the phosphor wheel.

The present invention also provides a method for producing a fluorescent material represented by the Formula (1),
the method including the step of firing a raw material obtained by mixing an M1 compound which is a raw material of the M1 element, an M2 compound which is a raw material of the M2 element, and an Al compound which is a raw material of the Al element, wherein:
   the Al compound has a purity of 99.9% by mass or more and a specific surface area of 0.01 to 5.0 m²/g; and
   the firing step is performed at a temperature of 1250 to 1700° C.

### Effect of the Invention

The present invention can provide a fluorescent material having excellent emission intensity.

### MODE FOR CARRYING OUT THE INVENTION

Hereinafter, embodiments of the present invention will be described.

### Fluorescent Material

A fluorescent material of the present invention is a compound represented by Formula:

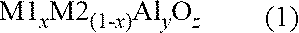

wherein: M1 and M2 represent one or more different metal elements; × satisfies 0.001 ≤ × ≤ 0.3; y satisfies 1.2 ≤ y ≤ 11.3; and z satisfies 2.8 ≤ z ≤ 18,
the fluorescent material having a sodium content of 1700 ppm by mass or less and a specific surface area of 0.01 to 4.30 m²/g.

The M1 is preferably a metal element selected from the group consisting of manganese, cerium, praseodymium, neodymium, samarium, europium, gadolinium, terbium, dysprosium, thulium, and ytterbium, more preferably a metal element selected from the group consisting of manganese, europium, cerium, terbium, and dysprosium, and still more preferably manganese. The M2 is preferably magnesium.

The fluorescent material of the present invention may be a fluorescent material represented by Formula (2) and containing a divalent metal M3 different from M1 and M2 from the viewpoint of suppressing the concentration quenching of M1 and increasing emission intensity.

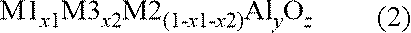

M3 is preferably at least one metal element selected from the group consisting of zinc, cerium, praseodymium, neodymium, samarium, europium, gadolinium, terbium, dysprosium, thulium, and ytterbium, and more preferably zinc.

The fluorescent material of Formula (1), wherein M1 is manganese and M2 is magnesium, or the fluorescent material of Formula (2), wherein M1 is manganese, M2 is magnesium, and M3 is zinc, may be a green-emitting fluorescent material containing manganese as a light-emitting center ion and emitting green light.

When the fluorescent material is irradiated with excitation light, the light-emitting center ion contained in the fluorescent material absorbs the excitation light, and an electron at a ground level transitions to an excitation level. When the excited electron returns from the excited level to the ground level again, energy corresponding to a difference in energy level is emitted as fluorescence. The transition probability of electrons from the ground level to the excited level varies depending on the electron arrangement of the light-emitting center ion, and in the case of a forbidden transition with a small transition probability, the absorbance is small and the emission intensity is apparently low. Meanwhile, in the case of an allowed transition having a large transition probability, the absorbance is large and the emission intensity is apparently high.

Manganese (Mn²⁺) has five electrons in the 3d orbit, and the transition to the excited level by light irradiation is a forbidden transition between the same kind orbitals (d-d), whereby the light absorption is small and the light emission is also weak. Meanwhile, for example, europium (Eu²⁺), which is a rare earth, has seven electrons in the 4f orbital, and the transition to the excited level by light irradiation is an allowed transition between different orbitals (f-d), whereby the light absorption is large and the light emission is also strong.

The emission intensity of the compound varies depending on the absorbance (number of absorbed photons) of the compound. In compounds having different absorbances, such as manganese and europium, it is inappropriate to determine the superiority or inferiority of emission characteristics by comparing apparent emission intensities. The emission characteristics of the compounds having different absorbances can be appropriately compared, for example, by using emission intensity in which a difference in absorbance is corrected, that is, quantum efficiency.

Definition: “Quantum Efficiency (Quantum Yield) = Emission Intensity (Number of Fluorescent Photons)/Absorbance (Number of Absorbed Photons)”

The M1 may be one metal element selected from the group consisting of manganese, cerium, praseodymium, neodymium, samarium, europium, gadolinium, terbium, dysprosium, thulium, and ytterbium, and may be two or more kinds of metal elements. The M1 may be, for example, a combination of manganese and at least one metal element selected from europium, cerium, terbium, and dysprosium.

In the Formula (1), × satisfies 0.001 ≤ × ≤ 0.3, for example, 0.005 ≤ × ≤ 0.2, preferably 0.01 ≤ × ≤ 0.1, more preferably 0.02 ≤ × ≤ 0.08, and particularly preferably 0.02 ≤ × ≤ 0.05. When × is less than 0.001, the amount of the element M1 as a light-emitting center is small, and the emission intensity decreases. When × is more than 0.3, the emission intensity decreases due to an interference phenomenon called concentration quenching between the elements M1.

In the formula (1), y satisfies 1.2 ≤ y ≤ 11.3, for example, 1.3 ≤ y ≤ 8.5, preferably 1.4 ≤ y ≤ 5.5, more preferably 1.5 ≤ y ≤ 2.5, and particularly preferably 1.5 ≤ y ≤ 2.0. z satisfies 2.8 ≤ z ≤ 18, for example, 3.0 ≤ z ≤ 13.0, preferably 3.3 ≤ z ≤ 8.5, more preferably 3.5 ≤ z ≤ 4.5, and particularly preferably 3.5 ≤ z ≤ 4.0. When the values of y and z do not fall within these ranges, the host crystal of the fluorescent material has an unstable structure, and the quenching process increases, so that the emission intensity decreases.

In the formula (2), ×1 and ×2 satisfy 0.012 ≤ ×1 + ×2 ≤ 0.14, and ×1 and ×2 satisfy 1.4 ≤ ×1/×2 ≤ 1.8.

The upper limit and the lower limit of each of the numerical values of ×, y, and z can be appropriately combined and selected from the values of the above ranges in order to obtain a target fluorescent material.

In a preferred embodiment of the fluorescent material of the present invention, the crystal structure is a spinel structure. The spinel structure is a crystal structure belonging to a cubic system, and is represented by the chemical formula: AB₂X₄. An A site in the spinel structure is surrounded by anions of four X sites, and forms an isolated tetrahedron. A B site in the spinel structure is surrounded by six anions, and forms an octahedron sharing sides. An oxide in which A is a divalent metal element, B is a trivalent metal element, and X is oxygen is found. When the crystal structure of the fluorescent material is the spinel structure, the fluorescent material is protected from external influences such as heat, ion bombardment, and vacuum ultraviolet irradiation, and at the same time, the emission intensity of the fluorescent material can be improved.

The fluorescent material of the present invention may contain sodium (Na) derived from a raw material. The content of sodium can be measured by an inductively coupled plasma (ICP) measurement method. Here, the inductively coupled plasma (ICP) measurement method is an emission spectroscopic analysis method using high frequency inductively coupled plasma (ICP) as a light source. In the method, an atomized sample solution is introduced into Ar plasma, and light emitted when an excited element returns to a ground state is spectrally dispersed, so that qualitative and quantitative determination of the element can be performed.

The content of sodium contained in the fluorescent material of the present invention is 1700 ppm by mass or less. When the content of sodium is more than 1700 ppm by mass, the alignment of aluminum and magnesium in the host crystal of the fluorescent material is disturbed, whereby the crystal structure becomes unstable, and the emission intensity of the fluorescent material decreases. The content of sodium contained in the fluorescent material of the present invention is preferably 150 ppm by mass or less, more preferably 110 ppm by mass or less, preferably 80 ppm by mass or less, still more preferably 50 ppm by mass or less, and yet still more preferably 15 ppm by mass or less. The content of sodium contained in the fluorescent material of the present invention is usually 10 ppm by mass or more.

The specific surface area of the fluorescent material of the present invention can be measured by, for example, the BET method. The BET method is one of methods for measuring the surface area of a powder by a gas phase adsorption method. The total surface area per 1 g of a sample, that is, the specific surface area can be determined from an adsorption isotherm. As an adsorption gas, nitrogen gas is usually used, and an adsorption amount is measured from a change in the pressure or volume of a gas to be adsorbed. The adsorption amount is determined based on the BET equation, and the surface area can be obtained by multiplying an area occupied by one adsorption molecule on the surface.

The fluorescent material of the present invention has a specific surface area of 0.01 to 4.3 m²/g. When the specific surface area of the fluorescent material is small, an area that can receive the excitation light becomes small with respect to the amount of the fluorescent material, the proportion of molecules that undergo the absorption and emission processes of the excitation light decreases, whereby the emission intensity decreases. When the specific surface area of the fluorescent material of the present invention is less than 0.01 m²/g, the emission intensity decreases, and even when the specific surface area of the fluorescent material is more than 4.3 m²/g, defects caused by the surface of the fluorescent material increase, so that the emission intensity decreases.

The specific surface area of the fluorescent material of the present invention is preferably 0.05 to 4.0 m²/g, more preferably 0.05 to 3.0 m²/g, still more preferably 0.05 to 0.8 m²/g, and yet still more preferably 0.05 to 0.16 m²/g.

In a preferred embodiment, the fluorescent material according to the present invention exhibits an excitation wavelength in the vicinity of 450 nm. When excitation is performed at an excitation wavelength λₑₓ = 450 nm and an emission spectrum is measured, an emission spectrum of green emission can be obtained in a range of 510 nm to 550 nm.

A method for producing the fluorescent material of the present invention will be described below.

### Producing Method

As raw materials of the fluorescent material of the present invention, an M1 compound which is a raw material of an M1 element, an M2 compound which is a raw material of an M2 element, and an Al compound which is a raw material of an Al element are used. Examples of the M1 compound which is the raw material of the M1 element include an oxide containing M1, a carbonate containing M1, a nitrate containing M1, an acetate containing M1, a fluoride containing M1, and a chloride containing M1. Examples of the M2 compound which is the raw material of the M2 element include an oxide containing M2, a carbonate containing M2, a nitrate containing M2, an acetate containing M2, a fluoride containing M2, and a chloride containing M2. Examples of the M3 compound which is the raw material of the M3 element include an oxide containing M3, a carbonate containing M3, a nitrate containing M3, an acetate containing M3, a fluoride containing M3, and a chloride containing M3.

Specific examples of these compounds include manganese oxide, manganese carbonate, manganese nitrate, manganese acetate, manganese fluoride, and manganese chloride as the M1 compound. Examples of the M2 compound include magnesium oxide, magnesium carbonate, magnesium nitrate, magnesium acetate, magnesium fluoride, and magnesium chloride. Examples of the M3 compound include zinc oxide, zinc carbonate, zinc nitrate, zinc acetate, zinc fluoride, and zinc chloride. Examples of the Al compound include aluminum oxide, aluminum carbonate, and aluminum nitrate.

As the raw materials, high-purity raw materials are used from the viewpoint of reducing the sodium content of the obtained fluorescent material. When low-purity raw materials are used, the sodium content in the obtained fluorescent material may be increased. In particular, as the Al compound as the main component of the fluorescent material, an Al compound having a purity of 99.8% by mass or more, preferably 99.9% by mass or more, and more preferably 99.99% by mass or more is used.

From the viewpoint of optimizing the specific surface area of the obtained fluorescent material, aluminum oxide having a specific surface area of 0.01 to 5.0 m²/g, preferably 0.05 to 4.5 m²/g, more preferably 0.05 to 3.0 m²/g, still more preferably 0.05 to 0.8 m²/g, and yet still more preferably 0.05 to 0.1 m²/g is used.

First, an M1 compound, an M2 compound, an Al compound, and if necessary, an M3 compound are weighed, blended, and mixed such that M1, M2, M3, Al, and O have a predetermined ratio. The blended raw materials can be mixed using a mixing apparatus, for example, a ball mill, a sand mill, and a pico mill and the like.

The mixed raw materials are then fired. The raw materials are fired in a temperature range of 1250 to 1700° C. When a firing temperature is 1700° C. or lower, a desired crystal structure can be obtained without collapsing the host crystal of the fluorescent material. The firing temperature is preferably 1300° C. to 1650° C., more preferably 1350° C. to 1600° C., and still more preferably 1400° C. to 1600° C. By firing at a high temperature, the reactivity of a solid solution is improved, and the crystallinity of the fluorescent material can be improved.

A firing atmosphere is preferably a mixed atmosphere of hydrogen and nitrogen. In the mixed atmosphere used for the firing atmosphere, the ratio of hydrogen to nitrogen is preferably 1:99 to 100:0, and more preferably 5:95 to 10:90.

When the firing temperature is in the above range, the firing time has no problem as long as the firing time is an industrially realistic time, but the firing time is, for example, 1 to 10 hours, and preferably 2 to 8 hours. When the firing time is within this range, a desired crystal structure can be obtained without collapsing the host crystal of the fluorescent material.

The fluorescent material of the present invention can be produced through a series of the steps including mixing and firing. The fluorescent material of the present invention may be produced using the solid phase reaction method, or may be synthesized using another production method, for example, a solution method or a melt synthesis method or the like.

Hereinafter, a fluorescent material having a core-shell structure according to an embodiment of the present invention will be described. In the formula (A) showing the elemental composition of a core part, examples of a metal element M include at least one metal element selected from the group consisting of manganese, strontium, cerium, praseodymium, neodymium, samarium, europium, gadolinium, terbium, dysprosium, thulium, zinc, and ytterbium. The metal element M is preferably at least one metal element selected from the group consisting of manganese, strontium, europium, terbium, and zinc, more preferably at least one metal element selected from zinc, manganese, and strontium, and still more preferably manganese.

When the metal element M is manganese, manganese constitutes a light-emitting center ion, and the fluorescent material may be a green light-emitting fluorescent material that emits green light.

The composition ratio × of the metal element M satisfies 0.001 ≤ × ≤ 0.3, for example, 0.005 ≤ × ≤ 0.3, preferably 0.01 ≤ × ≤ 0.2, more preferably 0.05 ≤ × ≤ 0.15, still more preferably 0.05 ≤ × ≤ 0.1, and particularly preferably 0.05 ≤ × ≤ 0.08. When × is less than 0.001, the amount of the metal element M constituting a light-emitting center ion is small, and the emission intensity is apt to decrease. When × is more than 0.3, the emission intensity is apt to decrease due to an interference phenomenon called concentration quenching between the metal elements M. The composition ratio a of Mg satisfies 0 ≤ a ≤ 1.0 ×, for example, 0 ≤ a ≤ 0.95.

The composition ratio y of Al satisfies 1.2 ≤ y ≤ 11.3, for example, 1.3 ≤ y ≤ 8.5, preferably 1.4 ≤ y ≤ 5.5, more preferably 1.5 ≤ y ≤ 2.5, and particularly preferably 1.5 ≤ y ≤ 2.3. The composition ratio z of O satisfies 2.8 ≤ z ≤ 18, for example, 3.0 ≤ z ≤ 13.0, preferably 3.3 ≤ z ≤ 8.5, more preferably 3.5 ≤ z ≤ 4.5, and particularly preferably 3.5 ≤ z ≤ 4.0. The composition ratio w of N satisfies 0 ≤ w ≤ 1.0. When the composition ratios y, z, and w do not fall within these ranges, the host crystal of the fluorescent material has an unstable structure, and the quenching process increases, so that the emission intensity is apt to decrease.

In one embodiment, the composition ratio a of Mg satisfies 0.1 ≤ a ≤ 0.98, for example 0.3 ≤ a ≤ 0.95, preferably 0.5 ≤ a ≤ 0.94, more preferably 0.7 ≤ a ≤ 0.93, still more preferably 0.8 ≤ a ≤ 0.93, and particularly preferably 0.85 ≤ a ≤ 0.93. The composition ratio y of Al satisfies 1.25 ≤ y ≤ 10.3, for example 1.35 ≤ y ≤ 7.0, preferably 1.45 ≤ y ≤ 3.5, more preferably 1.65 ≤ y ≤ 2.4, still more preferably 1.85 ≤ y ≤ 2.2, and particularly preferably 1.95 ≤ y ≤ 2.1. The composition ratio z of O satisfies 2.9 ≤ z ≤ 15.0, for example 3.15 ≤ z ≤ 10.5, preferably 3.4 ≤ z ≤ 6.5, more preferably 3.6 ≤ z ≤ 4.0, and still more preferably 3.7 ≤ z ≤ 4.0.

The upper limit and the lower limit of the numerical value of each of ×, a, y, and z can be appropriately combined and selected from the values of the above ranges in order to obtain a desired fluorescent material.

In the fluorescent material having the core-shell structure of the present invention, the core part has a sodium content of 1700 ppm by mass or less and a specific surface area of 0.01 to 4.30 m²/g. The sodium content and the specific surface area of the core part can be adjusted in the same manner as in the above-described fluorescent material of the present invention. The shell part is generally an oxide containing at least one element selected from the group consisting of boron and silicon. In a preferred embodiment of the fluorescent material of the present invention, the shell part contains a metal element M.

The amount of the shell part is 30% by weight or less, preferably 0.01 to 20% by weight, and more preferably 0.05 to 10% by weight, based on the core part. When the amount of the shell part is more than 30% by weight based on the core part, the proportion of the core part to the total weight of the fluorescent material decreases, and the emission intensity of the fluorescent material is apt to decrease.

Since the crystal structure of the surface of a crystal phase is apt to collapse, a defect part having no light emission properties is formed. For example, when the metal element M constitutes the light-emitting center ion, the metal element M on the surface of the crystal phase is considered to form the defect part to reduce the emission intensity. Meanwhile, when the surface of the crystal phase is covered with the shell part, the metal element M forming the defect part on the surface of the crystal layer is considered to migrate to the shell part, whereby the defect part of the crystal phase decreases and the emission intensity increases.

An effect of improving the emission intensity of the fluorescent material by forming the shell part on the surface of the crystal phase is due to a mechanism of improving the efficiency of generated light to exit to the outside of a crystallite. This mechanism does not increase the amount of light generated by optimizing the elemental composition of the crystal phase. Therefore, the effect of the present invention is considered to be achieved regardless of the elemental composition of the crystal phase.

The shell part present on the surface of the crystal phase contained in the fluorescent material of the present invention can be confirmed by detecting boron or/and silicon constituting the shell part by composition analysis such as X-ray photoelectron spectroscopy (XPS), energy dispersive X-ray spectroscopy (EDX), or inductively coupled plasma atomic emission spectroscopy (ICP-AES).

The core-shell structure of the fluorescent material of the present invention can be confirmed by performing EDX measurement of the cross section of the fluorescent material to obtain an element mapping image. In the element mapping image, a region where the metal element M and boron or/and silicon coexist becomes the shell part. From the results of the EDX measurement, a ratio Y/X of a peak area value Y of boron or silicon to a peak area value X of the metal element M present in the shell part can be calculated. When both boron and silicon are contained in the shell part, either a ratio Y(B)/X or a ratio Y (Si)/X calculated based on the peak area value Y(B) of boron and the peak area value Y(Si) of silicon is used as the ratio Y/X.

A method for calculating the peak area value of each element from the results of the EDX measurement will be described. A peak at which the intensity of a characteristic X-ray is the highest in an element of interest, that is, a peak detected with the highest intensity among peaks derived from the element of interest is selected. In the peak, a point at which the peak rises is determined on each of a high energy side and a low energy side. The point at which the peak rises refers to a start point from which the peak monotonically increases toward a peak top. A point having a low intensity is selected from the two start points, and the intensity of the point is defined as the background, that is, 0. The peaks are integrated with reference to the background between the two points where the peak rises. The calculated integrated value is defined as the peak area value of the element. In particular, in manganese, two points of 5.66 keV and 6.15 keV are defined as points at which peaks rise. Among these two points, a point having a lower intensity is defined as 0, and peaks are integrated between the two points. This integrated value is defined as the peak area value of manganese. In boron, two points of 0.14 keV and 0.23 keV are defined as points at which peaks rise. Among these two points, a point having a lower intensity is defined as 0, and peaks are integrated between the two points. This integrated value is defined as the peak area value of boron. In silicon, two points of 1.60 keV and 1.95 keV are defined as points at which peaks rise. Among these two points, a point having a lower intensity is defined as 0, and peaks are integrated between the two points. This integrated value is defined as the peak area value of silicon.

Y/X in the fluorescent material of the present invention satisfies, for example, 0 < Y/X ≤ 0.095, preferably 0 < Y/X ≤ 0.06, and more preferably 0 < Y/X ≤ 0.05. When Y/X is 0, the metal element M on the surface of the crystal phase forms the defect part, and the emission intensity is apt to decrease. When Y/X is more than 0.095, the metal element M excessively migrates to the shell part, so that the metal element in the core part decreases, and the emission intensity is apt to decrease.

In the fluorescent material of the present invention, the metal element M forms an intermediate with an element constituting the shell part when the raw material of the shell part is liquefied. Therefore, the metal element M is present in the shell part of the core-shell structure, and X is not 0. That is, in the fluorescent material of the present invention, the metal element M is necessarily detected from the shell part. When both boron and silicon are not detected, Y/X = 0 is defined.

In the EDX measurement, a suitable measurement method can be selected according to the thickness of a sample to be measured. Examples of the measurement method include SEM-EDX, TEM-EDX, and STEM-EDX. In order to accurately detect boron in the EDX measurement, windowless EDX is preferably used.

From the viewpoint of high spatial resolution and allowing observation of many cross sections of the fluorescent material at a time, a method is preferable, in which the fluorescent material is processed by an ion milling apparatus to obtain the cross section of the fluorescent material, and the cross section of the fluorescent material is then subjected to SEM-EDX measurement. In the calculation of Y/X using the present method, it is preferable to analyze 20 or more shell parts and use the average value thereof from the viewpoint of enhancing accuracy. From the viewpoint of improving the shape of the spectrum, the acceleration voltage of the SEM is preferably set to 20 kV.

### Composition

The fluorescent material of the present invention can be used as a composition in a state where the fluorescent material is dispersed in a monomer, a resin, or a mixture of a monomer and a resin. The resin component of the composition may be a polymer obtained by polymerizing a monomer.

Examples of the monomer used in the composition include methyl (meth)acrylate, ethyl (meth)acrylate, methoxyethyl (meth)acrylate, ethoxyethyl (meth)acrylate, n-propyl (meth)acrylate, isopropyl (meth)acrylate, n-butyl (meth)acrylate, isobutyl (meth)acrylate, tert-butyl (meth)acrylate, 2-ethylhexyl (meth)acrylate, cyclohexyl (meth)acrylate, heptyl (meth)acrylate, octyl (meth)acrylate, nonyl (meth)acrylate, dodecyl (meth)acrylate, lauryl (meth)acrylate, stearyl (meth)acrylate, cyclopentyl (meth)acrylate, cyclohexyl (meth)acrylate, 2-methylcyclohexyl (meth)acrylate, isobornyl (meth)acrylate, adamantyl (meth)acrylate, allyl (meth)acrylate, propargyl (meth)acrylate, phenyl (meth)acrylate, naphthyl (meth)acrylate, benzyl (meth)acrylate, nonylphenylcarbitol (meth)acrylate, 2-hydroxy-3-phenoxypropyl (meth)acrylate, 2-ethylhexylcarbitol (meth)acrylate, 2-hydroxyethyl (meth)acrylate, 2-hydroxypropyl (meth)acrylate, ethylene glycol di(meth)acrylate, triethylene glycol di(meth)acrylate, neopentyl glycol di(meth)acrylate, 1,6-hexanediol di(meth)acrylate, 1,7-heptanediol di(meth)acrylate, 1,8-ocatanediol di(meth)acrylate, 1,9-nonanediol di(meth)acrylate, 1,10-decanediol di(meth)acrylate, bis[(meth)acryloyloxyethyl] ether of bisphenol A, 3-ethylpentanediol di(meth)acrylate, trimethylolpropane tri(meth)acrylate, pentaerythritol tri(meth)acrylate, pentaerythritol tetra(meth)acrylate, dipentaerythritol penta(meth)acrylate, dipentaerythritol hexa(meth)acrylate, tripentaerythritol octa(meth)acrylate, tripentaerythritol hepta(meth)acrylate, tetrapentaerythritol deca(meth)acrylate, tetrapentaerythritol nona(meth)acrylate, ethylene glycol modified trimethylolpropane tri(meth)acrylate, propylene glycol modified trimethylolpropane tri(meth)acrylate, ethylene glycol modified pentaerythritol tetra(meth)acrylate, propylene glycol modified pentaerythritol tetra(meth)acrylate, ethylene glycol modified dipentaerythritol hexa(meth)acrylate, propylene glycol modified dipentaerythritol hexa(meth)acrylate, caprolactone modified pentaerythritol tetra(meth)acrylate, caprolactone modified dipentaerythritol hexa(meth)acrylate, dipentaerythritol penta(meth)acrylate succinic acid monoester, tris(2-(meth)acryloyloxyethyl)isocyanurate, and dicyclopentanyl(meth)acrylate.

Preferred examples of the (meth) acrylate include isobornyl (meth)acrylate, stearyl (meth)acrylate, methyl (meth)acrylate, cyclohexyl (meth)acrylate, and dicyclopentanyl (meth)acrylate from the viewpoint of improving heat resistance, water resistance, light resistance, and emission intensity.

These monomers may be used singly or in combination of two or more kinds thereof.

The resin used in the composition is not particularly limited, and examples thereof include a (meth)acrylic resin, a styrene resin, an epoxy resin, a urethane resin, and a silicone resin.

The silicone resin is not particularly limited, and examples thereof include an addition polymerizable silicone polymerized by an addition polymerization reaction of a silyl group and a vinyl group, and a condensation polymerizable silicone polymerized by condensation polymerization of an alkoxysilane. From the viewpoint of improving heat resistance, water resistance, light resistance, and emission intensity, an addition polymerizable silicone is preferable.

The silicone resin is preferably a silicone resin in which an organic group is bonded to a Si element in a silicone, and examples thereof include functional groups such as an alkyl group (such as a methyl group, an ethyl group, or a propyl group), a phenyl group, and an epoxy group. From the viewpoint of improving heat resistance, water resistance, light resistance, and emission intensity, a phenyl group is preferable.

Examples of the silicone resin include KE-108 (manufactured by Shin-Etsu Chemical Co., Ltd.), KE-1031 (manufactured by Shin-Etsu Chemical Co., Ltd.), KE-109E (manufactured by Shin-Etsu Chemical Co., Ltd.), KE-255 (manufactured by Shin-Etsu Chemical Co., Ltd.), KR-112 (manufactured by Shin-Etsu Chemical Co., Ltd.), KR-251 (manufactured by Shin-Etsu Chemical Co., Ltd.), and KR-300 (manufactured by Shin-Etsu Chemical Co., Ltd.).

These silicones may be used singly or in combination of two or more kinds thereof.

The proportion of the monomer component and/or the resin component contained in the composition is not particularly limited, and is 10% by weight or more and 99% by weight or less, preferably 20% by weight or more and 80% by weight or less, and more preferably 30% by weight or more and 70% by weight or less.

The composition may contain a curing agent from the viewpoint of curing the monomer component and/or the resin component to improve heat resistance, water resistance, light resistance, and emission intensity. Examples of the curing agent include a curing agent having a plurality of functional groups. Examples of the curing agent having a plurality of functional groups include trimethylolpropane triacrylate, pentaerythritol tetraacrylate, ditrimethylolpropane tetraacrylate, dipentaerythritol hexaacrylate, and a mercapto compound containing a thiol group.

The proportion of the curing agent contained in the composition is not particularly limited, and is 0.1% by weight or more and 20% by weight or less, preferably 1% by weight or more and 10% by weight or less, and more preferably 2% by weight or more and 7% by weight or less.

The composition may contain an initiator from the viewpoint of polymerizing a monomer component and/or a resin component to improve heat resistance, water resistance, light resistance, and emission intensity. The initiator may be a photopolymerizable initiator or a thermopolymerizable initiator.

The thermal polymerization initiator used in the present invention is not particularly limited, and examples thereof include an azo-based initiator, a peroxide initiator, a persulfate initiator, and a redox initiator.

The azo-based initiator is not particularly limited, and examples thereof include 2,2′-azobis(4-methoxy-2,4-dimethylvaleronitrile), 2,2′-azobis(2-amidinopropane)bihydrochloride, 2,2′-azobis(2,4-dimethylvaleronitrile), 2,2′-azobis(isobutyronitrile), 2,2′-azobis-2-methylbutyronitrile, 1,1-azobis(1-cyclohexanecarbonitrile), 2,2′-azobis(2-cyclopropylpropionitrile), and 2,2′-azobis(methyl isobutyrate).

The peroxide initiator is not particularly limited, and examples thereof include benzoyl peroxide, acetyl peroxide, lauroyl peroxide, decanoyl peroxide, dicumyl peroxide, dicetyl peroxydicarbonate, t-butylperoxyisopropyl monocarbonate, di(4-t-butylcyclohexyl)peroxydicarbonate, di(2-ethylhexyl)peroxydicarbonate, t-butylperoxypivalate, and t-butylperoxy-2-ethylhexanoate.

The persulfate initiator is not particularly limited, and examples thereof include potassium persulfate, sodium persulfate, and ammonium persulfate.

The redox (oxidation-reduction) initiator is not particularly limited, and examples thereof include any combination of the persulfate initiator with a reducing agent (such as sodium hydrogenmetasulfite, or sodium hydrogensulfite); any system based on an organic peroxide with a tertiary amine, for example, a system based on benzoyl peroxide with dimethylaniline; and any system based on an organic hydroperoxide with a transition metal, for example, a system based on cumene hydroperoxide with cobalt naphthate.

The other initiator is not particularly limited, and examples thereof include pinacols such as tetraphenyl 1,1,2,2-ethanediol.

The thermal polymerization initiator is preferably an azo-based initiator and a peroxide-based initiator, and more preferably 2,2′-azobis(methyl isobutyrate), t-butyl peroxypivalate, di(4-t-butylcyclohexyl)peroxydicarbonate, t-butyl peroxyisopropyl monocarbonate, and benzoyl peroxide.

The photopolymerization initiator is not particularly limited, and examples thereof include oxime-based compounds such as an O-acyloxime compound, alkylphenone compounds, and acylphosphine oxide compounds.

Examples of the O-acyloxime compound include N-benzoyloxy-1-(4-phenylsulfanylphenyl)butan-1-one-2-imine, N-benzoyloxy-1-(4-phenylsulfanylphenyl)octane-1-one-2-imine, N-benzoyloxy-1-(4-phenylsulfanylphenyl)-3-cyclopentylpropane-1-one-2-imine, N-acetoxy-1-[9-ethyl-6-(2-methylbenzoyl)-9H-carbazole-3-yl]ethane-1-imine, N-acetoxy-1-[9-ethyl-6-{2-methyl-4-(3,3-dimethyl-2,4-dioxacyclopentanylmethyloxy)benzoyl}-9H-carbazol-3-yl]ethane-1-imine, N-acetoxy-1-[9-ethyl-6-(2-methylbenzoyl)-9H-carbazole-3-yl]-3-cyclopentylpropane-1-imine, N-benzoyloxy-1-[9-ethyl-6-(2-methylbenzoyl)-9H-carbazole-3-yl]-3-cyclopentylpropane-1-one-2-imine, N-acetyloxy-1-[4-(2-hydroxyethyloxy)phenylsulfanylphenyl]propane-1-one-2-imine, and N-acetyloxy-1-[4-(1-methyl-2-methoxyethoxy)-2-methylphenyl]-1-(9-ethyl-6-nitro-9H-carbazole-3-yl)methane-1-imine.

Commercially available products such as IRGACURE (trade name) OXE01, OXE02, and OXE03 (all manufactured by BASF SE), and N-1919, NCI-930, and NCI-831 (all manufactured by ADEKA CORPORATION) may be used.

Examples of the alkylphenone compound include oligomers of 2-methyl-2-morpholino-1-(4-methylsulfanylphenyl)propane-1-one, 2-dimethylamino-1-(4-morpholinophenyl)-2-benzylbutane-1-one, 2-(dimethylamino)-2-[ (4-methylphenyl)methyl]-1-[4-(4-morpholinyl)phenyl]butane-1-one, 2-hydroxy-2-methyl-1-phenylpropane-1-one, 2-hydroxy-2-methyl-1-[4-(2-hydroxyethoxy)phenyl]propane-1-one, 1-hydroxycyclohexylphenyl ketone, and 2-hydroxy-2-methyl-1-(4-isopropenylphenyl)propane-1-one, α, α-diethoxyacetophenone, and benzyldimethylketal.

Commercially available products such as Omnirad (trade name) 369, 907, and 379 (all manufactured by IGM Resins B.V.) may be used.

Examples of the acylphosphine oxide compound include phenylbis(2,4,6-trimethylbenzoyl)phosphine oxide (for example, trade name “omnirad 819” (manufactured by IGM Resins B.V.)) and 2,4,6-trimethylbenzoyldiphenylphosphine oxide. Further examples of the photopolymerization initiator include benzoin compounds such as benzoin, benzoin methyl ether, benzoin ethyl ether, benzoin isopropyl ether, and benzoin isobutyl ether; benzophenone compounds such as benzophenone, methyl o-benzoylbenzoate, 4-phenylbenzophenone, 4-benzoyl-4′-methyldiphenyl sulfide, 3,3′,4,4′-tetra(tert-butylperoxycarbonyl)benzophenone, 2,4,6-trimethylbenzophenone, and 4,4′-di(N,N′-dimethylamino)-benzophenone; xanthone compounds such as 2-isopropylthioxanthone and 2,4-diethylthioxanthone; anthracene compounds such as 9,10-dimethoxyanthracene, 2-ethyl-9,10-dimethoxyanthracene, 9,10-diethoxyanthracene, and 2-ethyl-9,10-diethoxyanthracene; quinone compounds such as 9,10-phenanthrenequinone, 2-ethylanthraquinone, and camphorquinone; and benzil, methyl phenylglyoxylate, and titanocene compounds.

The composition may contain an antioxidant from the viewpoint of suppressing oxidation of the composition to improve heat resistance, water resistance, light resistance, and emission intensity. Examples of the antioxidant include an amine-based antioxidant, a sulfur-based antioxidant, a phenol-based antioxidant, a phosphorous-based antioxidant, a phosphorus-phenol-based antioxidant, and a metal compound-based antioxidant. The composition preferably contains at least one selected from the group consisting of an amine-based antioxidant, a sulfur-based antioxidant, a phenol-based antioxidant, and a phosphrous-based antioxidant, and more preferably at least one selected from the group consisting of a sulfur-based antioxidant, a phenol-based antioxidant, and a phosphorus-based antioxidant.

The amine-based antioxidant is an antioxidant having an amino group in the molecule. Examples of the amine-based antioxidant include naphthylamine-based antioxidants such as 1-naphthylamine, phenyl-1-naphthylamine, p-octylphenyl-1-naphthylamine, p-nonylphenyl-1-naphthylamine, p-dodecylphenyl-1-naphthylamine, and phenyl-2-naphthylamine; phenylenediamine-based antioxidants such as N,N′-diisopropyl-p-phenylenediamine, N,N′-diisobutyl-p-phenylenediamine, N,N′-diphenyl-p-phenylenediamine, N,N′-di-β-naphthyl-p-phenylenediamine, N-phenyl-N′-isopropyl-p-phenylenediamine, N-cyclohexyl-N′-phenyl-p-phenylenediamine, N-1,3-dimethylbutyl-N′-phenyl-p-phenylenediamine, dioctyl-p-phenylenediamine, phenylhexyl-p-phenylenediamine, and phenyloctyl-p-phenylenediamine; diphenylamine-based antioxidants such as dipyridylamine, diphenylamine, p,p′-di-n-butyldiphenylamine, p,p′-di-tert-butyldiphenylamine, p,p′-di-tert-pentyldiphenylamine, p,p′-dioctyldiphenylamine, p,p′-dinonyldiphenylamine, p,p′-didecyldiphenylamine, p,p′-didodecyldiphenylamine, p,p′-distyryldiphenylamine, p,p′-dimethoxydiphenylamine, 4,4′-bis(4-α,α-dimethylbenzoyl)diphenylamine, p-isopropoxydiphenylamine, and dipyridylamine; phenothiazine-based antioxidants such as phenothiazine, N-methylphenothiazine, N-ethylphenothiazine, 3,7-dioctylphenothiazine, phenothiazine carboxylic acid ester, and phenoselenazine; bis(2,2,6,6-tetramethyl-4-piperidinyl)sebacate (trade name “Tinuvin 770” manufactured by BASF SE); and [(4-methoxyphenyl)-methylene]-bis(1,2,2,6,6-pentamethyl-4-piperidinyl)malonate (trade name “Hostavin PR31” manufactured by Clariant AG).

The sulfur-based antioxidant is an antioxidant having a sulfur atom in the molecule. Examples of the sulfur-based antioxidant include dialkyl thiodipropionate compounds such as dilauryl, dimyristyl, or distearyl thiodipropionate (“SUMILIZER TPM” (trade name, manufactured by Sumitomo Chemical Co., Ltd.), and the like); β-alkylmercaptopropionic acid ester compounds of polyols such as tetrakis[methylene(3-dodecylthio)propionate]methane and tetrakis[methylene(3-laurylthio)propionate]methane; and 2-mercaptobenzimidazole.

The phenol-based antioxidant is an antioxidant having a phenolic hydroxy group in the molecule. In the present specification, a phosphorus-phenolic-based antioxidant having both a phenolic hydroxy group and a phosphorus acid ester structure or a phosphorus acid ester structure is classified as a phenolic-based antioxidant. Examples of the phenol-based antioxidant include 1,1,3-tris(2-methyl-4-hydroxy-5-tert-butylphenyl)butane, 4,4′-butylidene-bis(3-methyl-6-tert-butylphenol), 1,3,5-trimethyl-2,4,6-tris(3,5-di-tert-butyl-4-hydroxybenzyl)benzene, 2-tert-butyl-6-(3-tert-butyl-2-hydroxy-5-methylbenzyl)-4-methylphenyl acrylate, (tetrakis[methylene-3-(3,5-di-tert-butyl-4-hydroxyphenyl)propionate]methane, pentaerythritol tetrakis[3-(3,5-di-tert-butyl-4-hydroxyphenyl)propionate], octadecyl-3-(3,5-di-tert-butyl-4-hydroxyphenyl)propionate (“Irganox 1076″ (trade name, manufactured by BASF SE)), 3,3′,3”,5,5′,5″-hexa-tert-butyl-a,a′,a″-(mesitylen-2,4,6-triyl)tri-p-crezol, 1,3,5-tris(3,5-di-tert-butyl-4-hydroxybenzyl)-1,3,5-triazine-2,4,6(1H,3H,5H)-trione, 1,3,5-tris( (4-tert-butyl-3-hydroxy-2,6-xylyl)methyl)-1,3,5-triazine-2,4,6(1H,3H,5H)-trione, thiodiethylenebis[3-(3,5-di-tert-butyl-4-hydroxyphenyl)propionate], benzenepropanoic acid, 3,5-bis(1,1-dimethylethyl)-4-hydroxy C7-C9 side chain alkyl ester, 4,6-bis(octylthiomethyl)-o-crezol, 2,4-bis(n-octylthio)-6-(4-hydroxy 3′,5′-di-tert-butylanilino)-1,3,5-triazine, 3,9-bis(2-(3-(3-tert-butyl-4-hydroxy-5-methylphenyl)propionyloxy)-1,1-dimethylethyl)-2,4,8,10-tetraoxaspiro(5,5)undecane (manufactured by ADEKA CORPORATION, trade name “ADEKASTAB AO-80”), triethylene glycol bis[3-(3-tert-butyl-5-methyl-4-hydroxyphenyl)propionate], 4,4′-thiobis(6-tert-butyl-3-methylphenol), tris-(3,5-di-tert-butyl-4-hydroxybenzyl)-isocyanurate, 1,3,5-tris(4-tert-butyl-3-hydroxy-2,6-dimethylbenzyl)-isocyanurate, 1,6-hexanediol-bis[3-(3,5-di-tert-butyl-4-hydroxyphenyl)propionate], N,N′-hexamethylenebis(3,5-di-tert-butyl-4-hydroxy-hydrocinnamamide), 1,3,5-trimethyl-2,4,6-tris(3,5-di-tert-butyl-4-hydroxybenzyl)benzene, 1,6-hexanediol-bis-[3-(3,5-di-tert-butyl-4-hydroxyphenyl)propionate], 2,2′-methylenebis(4-methyl-6-tert-butylphenol), 1,3,5-tris(4-hydroxybenzyl)benzene, 6,6′-di-tert-butyl-4,4′-butylidenedi-m-cresol (manufactured by ADEKA CORPORATION, trade name “ADEKASTAB AO-40”), “Irganox 3125” (trade name, manufactured by BASF SE), “SUMILIZER BHT” (trade name, manufactured by Sumitomo Chemical Co., Ltd.), “SUMILIZER GA-80” (trade name, manufactured by Sumitomo Chemical Co., Ltd.), “SUMILIZER GS” (trade name, manufactured by Sumitomo Chemical Co., Ltd.), “Cyanox 1790” (trade name, manufactured by Cytec Industries Inc.), and vitamin E (manufactured by Eisai Co., Ltd.).

Examples of the phosphorus-phenol-based antioxidant include 2,10-dimethyl-4,8-di-tert-butyl-6-[3-(3,5-di-tert-butyl-4-hydroxyphenyl)propoxy]-12H-dibenzo[d,g][1,3,2]dioxaphosphocin, 2,4,8,10-tetra-tert-butyl-6-[3-(3,5-di-tert-butyl-4-hydroxyphenyl)propoxy]dibenzo[d,f] [1,3,2]dioxaphosphepin, and 2,4,8,10-tetra-tert-butyl-6-[3-(3,5-di-tert-butyl-4-hydroxyphenyl)propionyloxy]-dibenzo[d,f][1,3,2]dioxaphosphepin (manufactured by Sumitomo Chemical Co., Ltd., trade name “SUMILIZER GP”).

The phosphorus-based antioxidant is an antioxidant having a fluorescent materialic acid ester structure or fluorescent materialous acid ester structure. Examples of the phosphorus-based antioxidant include diphenyl isooctyl phosphite, 2,2′-methylenebis(4,6-di-tert-butylphenyl)octyl phosphite, diphenyl isodecyl phosphite, diphenyl isodecyl phosphite, triphenyl phosphate, tributyl phosphate, diisodecyl pentaerythritol diphosphite, distearyl pentaerythritol diphosphite, cyclic neopentanetetrayl bis(2,4-di-tert-butylphenyl)phosphite, cyclic neopentanetetrayl bis(2,6-di-tert-butylphenyl)phosphite, cyclic neopentanetetrayl bis(2,6-di-tert-butyl-4-methylphenyl)phosphite, 6-[3-(3-tert-butyl-4-hydroxy-5-methylphenyl)propoxy]-2,4,8,10-tetra-tert-butylbenzo[d,f][1,3,2]dioxaphosphepin, tris(nonylphenyl)phosphite (manufactured by ADEKA CORPORATION, trade name “ADEKASTAB 1178”), tris(mono- & dinonylphenyl mixed) phosphite, diphenyl mono(tridecyl) phosphite, 2,2′-ethylidenebis(4,6-di-tertbutylphenol)fluorophosphite, phenyl diisodecyl phosphite, tris(2-ethylhexyl) phosphite, tris(isodecyl) phosphite, tris(tridecyl) phosphite, tris(2,4-di-tert-butylphenyl) phosphite, tetrakis(2,4-di-tert-butylphenyl)-4,4′-biphenylene-di-phosphonite, 4,4′-isopropylidene diphenyl tetraalkyl(C12-C15) diphosphite, 4,4′-butylidenebis(3-methyl-6-tert-butylphenyl)-ditridecyl phosphite, bis(nonylphenyl)pentaerythritol diphosphite, bis(2,4-di-tert-butylphenyl)pentaerythritol diphosphite, cyclic neopentanetetrayl bis(2,6-di-tert-butyl-4-methylphenyl-phosphite), 1,1,3-tris(2-methyl-4-ditridecyl phosphite-5-tert-butylphenyl)butane, tetrakis(2,4-di-tert-butyl-5-methylphenyl)-4,4′-biphenylene diphosphonite, tri-2-ethylhexyl phosphite, triisodecyl phosphite, tristearyl phosphite, phenyl diisodecyl phosphite, trilauryl trithiophosphite, distearylpentaerythritol diphosphite, tris(nonylphenyl) phosphite, tris[2-[[2,4,8,10-tetra-tert-butyldibenzo[d,f] [1,3,2]dioxaphosphin-6-yl]oxy]ethyl]amine, bis(2,4-bis(1,1-dimethylethyl)-6-methylphenyl)ethyl ester fluorescent materialous acid, 3,9-bis(2,6-di-tert-butyl-4-methylphenoxy)-2,4,8,10-tetraoxa-3,9-diphosphaspiro[5.5]undecane, bis(2,4-di-tert-butylphenyl)pentaerythritol diphosphite, 2,2′-methylenebis(4,6-di-tert-butyl-1-phenyloxy) (2-ethylhexyloxy)phosphorus, triphenyl phosphite, 4,4′-butylidene-bis(3-methyl-6-tert-butylphenylditridecyl)phosphite, octadecyl phosphite, 9,10-dihydro-9-oxa-10-phosphaphenanthrene-10-oxide, 10-(3,5-di-tert-butyl-4-hydroxybenzyl)-9,10-dihydro-9-oxa-10-phosphaphenanthrene-10-oxide, 10-decyloxy-9,10-dihydro-9-oxa-10-phosphaphenanthrene-10-oxide, 2,2-methylenebis(4,6-di-tert-butylphenyl)octyl phosphite, tetrakis(2,4-di-tert-butylphenyl)[1,1-biphenyl]-4,4′-diyl bisphosphonite, bis[2,4-bis(1,1-dimethylethyl)-6-methylphenyl]ethyl ester phosphonic acid, “ADEKASTAB 329K” (trade name, manufactured by ADEKA CORPORATION), “ADEKASTAB PEP36” (trade name, manufactured by ADEKA CORPORATION), “ADEKASTAB PEP-8” (trade name, manufactured by ADEKA CORPORATION), “Sandstab P-EPQ” (trade name, manufactured by Clariant AG), “Weston 618” (trade name, manufactured by GE Specialty Chemicals Inc.), “Weston 619G” (trade name, manufactured by GE Specialty Chemicals Inc.), and “ULTRANOX 626” (trade name, manufactured by GE Specialty Chemicals Inc.).

The proportion of the antioxidant contained in the composition is not particularly limited, and is 0.1% by weight or more and 20% by weight or less, preferably 1% by weight or more and 10% by weight or less, and more preferably 2% by weight or more and 7% by weight or less.

The composition may contain a light scattering material from the viewpoint of scattering light passing through the composition to improve the amount of light absorbed by the composition to improve the emission intensity. The light scattering material is not particularly limited, and examples thereof include polymer fine particles and inorganic fine particles. Examples of the polymer used for the polymer fine particles include an acrylic resin, an epoxy resin, a silicone resin, and a urethane resin.

Examples of the inorganic fine particles used for the light scattering material include fine particles containing known inorganic compounds such as an oxide, a hydroxide, a sulfide, a nitride, a carbide, a chloride, a bromide, an iodide, and a fluoride.

In the light scattering material, examples of the oxide contained in the inorganic fine particles include known oxides such as silicon oxide, aluminum oxide, zinc oxide, niobium oxide, zirconium oxide, titanium oxide, magnesium oxide, cesium oxide, yttrium oxide, strontium oxide, barium oxide, calcium oxide, tungsten oxide, indium oxide, gallium oxide, and titanium oxide, and mixtures thereof. Among these, aluminum oxide, zinc oxide, and niobium oxide are preferable, and aluminum oxide and niobium oxide are more preferable. Niobium oxide is most preferable.

In the light scattering material, examples of the aluminum oxide contained in the inorganic fine particles include known aluminum oxides such as α-alumina, γ-alumina, θ-alumina, δ-alumina, η-alumina, κ-alumina, and χ-alumina. Among these, α-alumina and γ-alumina are preferable, and α-alumina is more preferable.

In the light scattering material, the aluminum oxide may be a commercially available product, and raw materials such as aluminum nitrate, aluminum chloride, and aluminum alkoxide may be fired to obtain alumina. Examples of the commercially available aluminum oxide include AKP-20 (manufactured by Sumitomo Chemical Co., Ltd.), AKP-30 (manufactured by Sumitomo Chemical Co., Ltd.), AKP-50 (manufactured by Sumitomo Chemical Co., Ltd.), AKP-53 (manufactured by Sumitomo Chemical Co., Ltd.), AKP-3000 (manufactured by Sumitomo Chemical Co., Ltd.), AA-02 (manufactured by Sumitomo Chemical Co., Ltd.), AA-03 (manufactured by Sumitomo Chemical Co., Ltd.), AA-04 (manufactured by Sumitomo Chemical Co., Ltd.), AA-05 (manufactured by Sumitomo Chemical Co., Ltd.), AA-07 (manufactured by Sumitomo Chemical Co., Ltd.), AA-1.5 (manufactured by Sumitomo Chemical Co., Ltd.), AA-3 (manufactured by Sumitomo Chemical Co., Ltd.), and AA-18 (manufactured by Sumitomo Chemical Co., Ltd.). From the viewpoint of absorbance, AA-02 (manufactured by Sumitomo Chemical Co., Ltd.), AA-3 (manufactured by Sumitomo Chemical Co., Ltd.), AA-18 (manufactured by Sumitomo Chemical Co., Ltd.), AKP-20 (manufactured by Sumitomo Chemical Co., Ltd.), AKP-3000 (manufactured by Sumitomo Chemical Co., Ltd.), AKP-53 (manufactured by Sumitomo Chemical Co., Ltd.), AKP-30 (manufactured by Sumitomo Chemical Co., Ltd.), and AKP-50 (manufactured by Sumitomo Chemical Co., Ltd.) are preferable, and AA-02 (manufactured by Sumitomo Chemical Co., Ltd.), AA-3 (manufactured by Sumitomo Chemical Co., Ltd.), AKP-53 (manufactured by Sumitomo Chemical Co., Ltd.), AKP-3000 (manufactured by Sumitomo Chemical Co., Ltd.), AKP-30 (manufactured by Sumitomo Chemical Co., Ltd.), and AKP-50 (manufactured by Sumitomo Chemical Co., Ltd.) are more preferable.

In the light scattering material, examples of the hydroxide contained in the inorganic fine particles include known oxides such as aluminum hydroxide, zinc hydroxide, magnesium hydroxide, cerium hydroxide, yttrium hydroxide, strontium hydroxide, barium hydroxide, calcium hydroxide, indium hydroxide, and gallium hydroxide, and mixtures thereof. Among these, aluminum hydroxide and zinc hydroxide are preferable.

In the light scattering material, examples of the sulfide contained in the inorganic fine particles include known sulfides such as silicon sulfide, aluminum sulfide, zinc sulfide, niobium sulfide, zirconium sulfide, titanium sulfide, magnesium sulfide, cerium sulfide, yttrium sulfide, strontium sulfide, barium sulfide, calcium sulfide, tungsten sulfide, indium sulfide, and gallium sulfide, and mixtures thereof. Among these, aluminum sulfide, zinc sulfide, and niobium sulfide are preferable, and zinc sulfide and niobium sulfide are more preferable. Niobium sulfide is most preferable.

In the light scattering material, examples of the nitride contained in the inorganic fine particles include known nitrides such as silicon nitride, aluminum nitride, zinc nitride, niobium nitride, zirconium nitride, titanium nitride, magnesium nitride, cerium nitride, yttrium nitride, strontium nitride, barium nitride, calcium nitride, tungsten nitride, indium nitride, and gallium nitride, and mixtures thereof. Among these, aluminum nitride, zinc nitride, and niobium nitride are preferable, and aluminum nitride and niobium nitride are more preferable. Niobium nitride is most preferable.

In the light scattering material, examples of the carbide contained in the inorganic fine particles include known sulfides such as silicon carbide, aluminum carbide, zinc carbide, niobium carbide, zirconium carbide, titanium carbide, magnesium carbide, cerium carbide, yttrium carbide, strontium carbide, barium carbide, calcium carbide, tungsten carbide, indium carbide, and gallium carbide, and mixtures thereof. Among these, aluminum carbide, zinc carbide, and niobium carbide are preferable, and aluminum carbide and niobium carbide are more preferable. Niobium carbide is most preferable.

In the light scattering material, examples of the chloride contained in the inorganic fine particles include known chlorides such as silicon chloride, aluminum chloride, zinc chloride, niobium chloride, zirconium chloride, titanium chloride, magnesium chloride, cerium chloride, yttrium chloride, strontium chloride, barium chloride, calcium chloride, tungsten chloride, indium chloride, and gallium chloride, and mixtures thereof. Among these, aluminum chloride, zinc chloride, and niobium chloride are preferable, and aluminum chloride and niobium chloride are more preferable. Niobium chloride is most preferable.

In the light scattering material, examples of the bromide contained in the inorganic fine particles include known bromides such as silicon bromide, aluminum bromide, zinc bromide, niobium bromide, zirconium bromide, titanium bromide, magnesium bromide, cerium bromide, yttrium bromide, strontium bromide, barium bromide, calcium bromide, tungsten bromide, indium bromide, gallium bromide, and mixtures thereof. Among these, aluminum bromide, zinc bromide, and niobium bromide are preferable, and aluminum bromide and niobium bromide are more preferable. Niobium bromide is most preferable.

In the light scattering material, examples of the iodide contained in the inorganic fine particles include known iodides such as silicon iodide, aluminum iodide, zinc iodide, niobium iodide, zirconium iodide, titanium iodide, magnesium iodide, and gallium iodide, cerium iodide, yttrium iodide, strontium iodide, barium iodide, calcium iodide, tungsten iodide, and indium iodide, and mixtures thereof. Among these, aluminum iodide, zinc iodide, and niobium iodide are preferable, and aluminum iodide and niobium iodide are more preferable. Niobium iodide is most preferable.

In the light scattering material, examples of the fluoride contained in the inorganic fine particles include known fluorides such as silicon fluoride, aluminum fluoride, zinc fluoride, niobium fluoride, zirconium fluoride, titanium fluoride, magnesium fluoride, cerium fluoride, yttrium fluoride, strontium fluoride, barium fluoride, calcium fluoride, tungsten fluoride, indium fluoride, and gallium fluoride, and mixtures thereof. Among these, aluminum fluoride, zinc fluoride, and niobium fluoride are preferable, and aluminum fluoride and niobium fluoride are more preferable. Niobium fluoride is most preferable.

As the light scattering material, aluminum oxide, silicon oxide, zinc oxide, titanium oxide, niobium oxide, and zirconium oxide are preferable, and aluminum oxide is preferable, from the viewpoint of scattering light passing through the composition to improve the amount of light absorbed by the composition and improve the emission intensity.

The particle size of the light scattering material contained in the composition is not particularly limited, and is 0.1 µm or more and 50 µm or less, preferably 0.3 µm or more and 10 µm or less, and more preferably 0.5 µm or more and 5 µm or less.

The proportion of the light scattering material contained in the composition is not particularly limited, and is 0.1% by weight or more and 20% by weight or less, preferably 1% by weight or more and 10% by weight or less, and more preferably 2% by weight or more and 7% by weight or less.

The composition may contain a light-emitting material other than the fluorescent material of the present invention from the viewpoint of adjusting the color of light emitted by the composition to achieve a high color gamut. Examples of the light-emitting material other than the fluorescent material of the present invention contained in the composition include a fluorescent material other than the fluorescent material of the present invention, and a quantum dot.

The quantum dot contained in the composition is not particularly limited as long as it is a quantum dot particle capable of emitting fluorescence in a visible light wavelength region. The quantum dot can be selected from the group consisting of, for example, a II-VI semiconductor compound; a III-V semiconductor compound; a IV-VI semiconductor compound; a IV element, or a compound containing the same; and combinations thereof. These can be used singly or in combination of two or more kinds thereof.

The II-VI semiconductor compound can be selected from the group consisting of: a binary compound selected from the group consisting of CdS, CdSe, CdTe, ZnS, ZnSe, ZnTe, ZnO, HgS, HgSe, HgTe, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, and mixtures thereof; and a quaternary compound selected from the group consisting of CdZnSeS, CdZnSeTe, CdZnSTe, CdHgSeS, CdHgSeTe, CdHgSTe, HgZnSeS, HgZnSeTe, HgZnSTe, and mixtures thereof.

The III-V semiconductor compound can be selected from the group consisting of: a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InNP, InNAs, InNSb, InPAs, InPSb, GaAlNP, and mixtures thereof; and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof.

The IV-VI semiconductor compound can be selected from the group consisting of: a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof.

The IV element or the compound containing the same can be selected from the group consisting of: an element compound selected from the group consisting of Si, Ge, and mixtures thereof; and a binary compound selected from the group consisting of SiC, SiGe, and mixtures thereof.

The quantum dot can have a homogeneous single structure; a dual structure such as core-shell or gradient structure; or a mixed structure thereof.

In the core-shell dual structure, the substances constituting the core and the shell can be composed of the aforementioned semiconductor compounds that are different from each other. For example, the core may contain one or more substances selected from the group consisting of CdSe, CdS, ZnS, ZnSe, ZnTe, CdTe, CdSeTe, CdZnS, PbSe, AgInZnS, HgS, HgSe, HgTe, GaN, GaP, GaAs, InP, InAs, and ZnO without limitation. For example, the shell may contain one or more substances selected from the group consisting of CdSe, ZnSe, ZnS, ZnTe, CdTe, PbS, TiO, SrSe, and HgSe without limitation.

From the viewpoint of obtaining white light, the quantum dot is preferably InP or CdSe.

The diameter of the quantum dot is not particularly limited, but red, green, and blue quantum dot particles can be classified by a particle size, and the particle size decreases in the order of red, green, and blue. Specifically, the red quantum dot particle may have a particle size of 5 nm or more and 10 nm or less, the green quantum dot particle may have a particle size of more than 3 nm and 5 nm or less, and the blue quantum dot particle may have a particle size of 1 nm or more and 3 nm or less. Upon irradiation of light, the red quantum dot particle emits red light, the green quantum dot particle emits green light, and the blue quantum dot particle emits blue light.

The fluorescent material other than the fluorescent material of the present invention contained in the composition is not particularly limited, and examples thereof include a sulfide-based fluorescent material, an oxide-based fluorescent material, a nitride-based fluorescent material, and a fluoride-based fluorescent material. These may be used singly or in combination of two or more kinds thereof.

Examples of the sulfide-based fluorescent material include CaS:Eu, SrS:Eu, SrGa₂S₄:Eu, CaGa₂S₄:Eu, Y₂O₂S:Eu, La₂O₂S:Eu, and Gd₂O₂S:Eu.

Specific examples of the oxide-based fluorescent material include (Ba,Sr)₃SiO₅:Eu, (Ba,Sr)₂SiO₄:Eu, Tb₃Al₅O₁₂:Ce, and Ca₃Sc₂Si₃O₁₂:Ce.

Specific examples of the nitride-based fluorescent material include CaSi₅N₈: Eu, Sr₂Si₅N₈: Eu, Ba₂Si₅N₈: Eu, (Ca,Sr,Ba)₂Si₅N₈:Eu, Cax(Al,Si)₁₂(O,N)₁₆:Eu (0<×≤1.5), CaSi₂O₂N₂ : Eu, SrSi₂O₂N₂ : Eu, BaSi₂O₂N₂ : Eu, (Ca, Sr, Ba) Si₂O₂N₂ : Eu, CaAl₂Si₄N₈:Eu, CaSiN₂:Eu, CaAlSiN₃:Eu, and (Sr,Ca)AlSiN₃:Eu.

Specific examples of the fluoride-based fluorescent material include, but are not particularly limited to, K₂TiF₆:Mn⁴⁺, Ba₂TiF₆:Mn⁴⁺, Na₂TiF₆:Mn⁴⁺, K₃ZrF₇:Mn⁴⁺, and K₂SiF₆ : Mn⁴⁺.

Specific examples of the other fluorescent material include, but are not particularly limited to, a YAG-based fluorescent material such as (Y,Gd)₃(Al,Ga)₅O₁₂:Ce(YAG:Ce); a sialon-based fluorescent material such as Lu(Si,Al)₁₂(O,N)₁₆:Eu; and a perovskite fluorescent material also having a perovskite structure.

The fluorescent material other than the fluorescent material of the present invention contained in the composition is preferably a red fluorescent material, and is preferably K₂SiF₆:Mn⁴⁺, from the viewpoint of obtaining white light.

The proportion of the fluorescent material other than the fluorescent material of the present invention contained in the composition is not particularly limited, and is 0.1% by weight or more and 90% by weight or less, preferably 1% by weight or more and 80% by weight or less, and more preferably 5% by weight or more and 60% by weight or less.

### Film

The fluorescent material of the present invention dispersed in a resin can be used as a film shape. The shape of the film is not particularly limited, and may be any shape such as a sheet shape or a bar shape. Here, the “bar shape” means, for example, a plan-view strip shape extending in one direction. Examples of the plan-view strip shape include a plate shape having different side lengths. The thickness of the film may be 0.01 µm to 1000 mm, 0.1 µm to 10 mm, or 1 µm to 1 mm. Here, the thickness of the film refers to a distance between a front surface and a back surface in a thickness direction of the film when a side having the smallest value among the length, the width, and the height of the film is defined as the “thickness direction”. Specifically, the thicknesses of the film are measured at any three points of the film using a micrometer, and an average value of the measured values at the three points is taken as the thickness of the film. The film may be a single-layered film or a multi-layered film. In the case of the multi-layered film, the layers may be composed of the same type of composition of the embodiment, or may be composed of different types of compositions of the embodiment.

### Glass Molded Body

The fluorescent material of the present invention dispersed in glass can be used as a glass molded body. A glass component used in a glass composition is not particularly limited, and examples thereof include SiO₂, P₂O₅, GeO₂, BeF₂, As₂S₃, SiSe₂, GeS₂, TiO₂, TeO₂, Al₂O₃, Bi₂O₃, V₂O₅, Sb₂O₅, PbO, CuO, ZrF₄, AlF₃, InF₃, ZnCl₂, ZnBr₂, Li₂O, Na₂O, K₂O, MgO, BaO, CaO, SrO, LiCl, BaCl, BaF₂, and LaF₃. Among these, SiO₂ or Bi₂O₃ is preferably contained as the glass component from the viewpoint of improving durability, heat resistance, and light resistance. The glass components may be used singly or in combination of two or more kinds thereof.

The proportion of the glass component contained in the glass molded body is not particularly limited, and is 10% by weight or more and 99% by weight or less, preferably 20% by weight or more and 80% by weight or less, and more preferably 30% by weight or more and 70% by weight or less.

The glass molded body may contain a light scattering material from the viewpoint of scattering light passing through the molded body to improve the amount of light absorbed by the glass molded body and improve the emission intensity. As the light scattering material, the same inorganic fine particles as those of the light scattering material used for the resin composition can be used.

The amount of the light scattering material added to the glass molded body may be the same as the amount of the light scattering material used for the resin composition.

The glass molded body may contain another light-emitting material other than the fluorescent material of the present invention from the viewpoint of adjusting the color of light emitted from the glass molded body to achieve a high color gamut. As another light-emitting material other than the fluorescent material of the present invention contained in the glass molded body, the same light-emitting material as that used for the resin composition can be used.

The amount of the light-emitting material added to the glass molded body may be the same as that of the light-emitting material used for the resin composition.

The shape of the glass molded body is not particularly limited, and examples thereof include a plate shape, a rod shape, a cylindrical shape, and a wheel shape.

### Light Emitting Element

The fluorescent material of the present invention can constitute a light emitting element together with the light source. As the light source, in particular, an LED that emits ultraviolet light having a wavelength of 350 nm to 500 nm or visible light can be used. When the fluorescent material of the present invention is irradiated with light having the above wavelength, the fluorescent material emits green light having a peak at a wavelength of 510 nm to 550 nm. Therefore, in the fluorescent material of the present invention, for example, an ultraviolet LED or a blue LED is used as the light source, and the fluorescent material is also combined with other red fluorescent material, whereby a white light emitting element can be constituted.

### Light Emitting Device

The fluorescent material of the present invention can constitute the white light emitting element as described above, and the white light emitting element can be used as a member of a light emitting device. In the light emitting device, the light emitting element is irradiated with light from the light source, and the light emitting element with which the light is irradiated emits light to extract the light.

### Display

The light emitting element including the fluorescent material of the present invention and the light source can be used for a display. Examples of such a display include a liquid crystal display capable of controlling the transmittance of light derived from a light emitting element with liquid crystal, and selecting and extracting transmitted light as red light, blue light, and green light by a color filter.

### Phosphor Wheel

The fluorescent material of the present invention can be used for producing a phosphor wheel. The phosphor wheel is a member including a disk-shaped substrate and a fluorescent material layer formed on the surface of the substrate. The phosphor wheel absorbs and excites excitation light emitted from the light source, and emits converted light having a different wavelength. For example, the phosphor wheel may absorb blue excitation light, emit converted light different from the blue excitation light converted by the fluorescent material layer, and reflect the blue excitation light to convert the blue excitation light into lights having various colors in conjunction with the converted light or utilizing only the converted light.

### Projector

The fluorescent material of the present invention can be used as a member constituting a projector using the phosphor wheel. The projector is a display device including a light source, a phosphor wheel, a mirror device, and a projection optical system.

### EXAMPLES

Hereinafter, the present invention will be described in more detail with reference to Examples. The present invention is not limited to these Examples.

### Example 1

As raw materials of a fluorescent material of the present invention, an aluminum oxide powder (grade AA-18 (purity: 99.99%, specific surface area: 0.1 m²/g), manufactured by Sumitomo Chemical Co., Ltd.), a magnesium oxide powder (MgO (purity 4N), manufactured by Kanto Chemical Co., Inc.), and a manganese carbonate powder (MnCO₃ (purity: 99.9%, manufactured by Aldrich) were used. In consideration that carbonic acid in manganese carbonate was desorbed as carbon dioxide (CO₂) after firing, the respective raw materials were weighed such that the fluorescent material after firing had a composition having a molar ratio of Mn:Mg:Al:O=0.05:0.95:2:4, and dry-mixed for 3 minutes. Next, the mixed raw materials were filled in an alumina container. Subsequently, the alumina container was set in an electric furnace, and a mixed gas of hydrogen:nitrogen=10:90 was introduced into the electric furnace. The raw materials were heated to 1350° C., fired for 4 hours, and then allowed to cool. The fired product was recovered from the container to obtain a fluorescent material of Example 1.

### Example 2

A fluorescent material of Example 2 was prepared in the same manner as in Example 1 except that grade AA-3 (purity: 99.99%, specific surface area: 0.5 m²/g, manufactured by Sumitomo Chemical Co., Ltd.) was used as an aluminum oxide powder.

### Example 3

A fluorescent material of Example 3 was prepared in the same manner as in Example 1 except that grade AKP-3000 (purity: 99.99%, specific surface area: 4.5 m²/g, manufactured by Sumitomo Chemical Co., Ltd.) was used as an aluminum oxide powder.

### Example 4

A fluorescent material of Example 4 was prepared in the same manner as in Example 1 except that mixed raw materials were fired at 1550° C.

### Comparative Example 1

A fluorescent material of Comparative Example 1 was prepared in the same manner as in Example 1 except that grade A-210 (purity: 99.7%, specific surface area: 0.5 m²/g, manufactured by Sumitomo Chemical Co., Ltd.) was used as an aluminum oxide powder.

### Comparative Example 2

A fluorescent material of Comparative Example 2 was prepared in the same manner as in Example 1 except that grade AA-03 (purity: 99.99%, specific surface area: 5.2 m²/g, manufactured by Sumitomo Chemical Co., Ltd.) was used as an aluminum oxide powder.

### Example 5

As raw materials of a fluorescent material of the present invention, an aluminum oxide powder (grade AA-18 (purity: 99.99%, specific surface area: 0.1 m²/g), manufactured by Sumitomo Chemical Co., Ltd.), a magnesium oxide powder (MgO (purity 99.99%), manufactured by Kojundo Chemical Laboratory Co., Ltd.), a zinc oxide powder (ZnO (purity 99.99%), manufactured by Kojundo Chemical Laboratory Co., Ltd.), and a manganese carbonate powder (MnCO₃ (purity 99.99%), manufactured by Kojundo Chemical Laboratory Co., Ltd.) were used. In consideration that carbonic acid in manganese carbonate was desorbed as carbon dioxide (CO₂) after firing, the respective raw materials were weighed such that the fluorescent material after firing had a composition having a molar ratio of Mn:Mg:Zn:Al:O=0.07:0.88:0.05:2:4 and a molar ratio of Mn/Zn=1.4, and dry-mixed for 3 minutes. Next, the mixed raw materials were filled in an alumina container. Subsequently, the alumina container was set in an electric furnace, and a mixed gas of hydrogen:nitrogen=10:90 was introduced into the electric furnace. The raw materials were heated to 1550° C., fired for 4 hours, and then allowed to cool. The fired product was recovered from the container to obtain a fluorescent material of Example 5.

### Example 6

A fluorescent material of Example 6 was prepared in the same manner as in Example 5 except that raw materials were weighed such that the fluorescent material after firing had a composition having a molar ratio of Mn:Mg:Zn:Al:O=0.09:0.86:0.05:2:4 and a molar ratio of Mn/Zn=1.8.

### <Various Measurements and Evaluations>

The following items were measured for the fluorescent materials produced in Examples and Comparative Examples.

### (A) Crystal Structure

For the fluorescent materials of Examples 1 to 6 and Comparative Examples 1 and 2, powder X-ray diffraction using CuK_{α} rays was performed using an X-ray diffractometer (“X′Pert Pro” (trade name) manufactured by PANalytical). In the obtained X-ray diffraction pattern, the same diffraction pattern as that of a spinel crystal was observed in all the samples. A main crystal phase was confirmed to have the same crystal structure as that of the spinel crystal.

### (B) Sodium Content

Each of the fluorescent materials of Examples 1 to 6 and Comparative Examples 1 and 2 was dissolved by a microwave heating method using an ICP emission spectrophotometer (“SPS3000” (trade name) manufactured by SII Nanotechnology Inc.), and the content of sodium in the fluorescent material was then analyzed under the condition of the presence of a chamber gas.

### (C) Specific Surface Area

For the fluorescent materials of Examples 1 to 6 and Comparative Examples 1 and 2, a specific surface area determined by the BET method was measured using a fully automatic specific surface area measuring apparatus (“MacsorbHM-1208” (trade name) manufactured by Mountec).

### (D) Emission Intensity

The emission spectra of the fluorescent materials of Example 1 to 6 and Comparative Examples 1 and 2 were measured using a spectrofluorometer (“FP-6500” (trade name) manufactured by JASCO Corporation). In the measurement, an emission spectrum at an excitation wavelength of 450 nm was measured using a solid sample holder attached to a photometer. All the fluorescent materials showed green emission. A spectrum area at a peak wavelength was calculated from the measured spectrum, and evaluated as emission intensity. The emission intensity of each fluorescent material was evaluated on the basis of whether it was at a level capable of being used for a light emitting element. That is, the emission intensity of a fluorescent material that is evaluated as average or more is at a level that can be used for a light emitting element.

When the emission intensity of the fluorescent material of Example 1 is 100%,
AA means that the emission intensity is 170% or more (best);
A means that the emission intensity is 100% or more (good);
B means that the emission intensity is 40% or more (acceptable); and
C means that the emission intensity is less than 40% (not acceptable).

The measurement results and the above evaluations of Examples and Comparative Examples are shown in Tables 1 and 2.

TABLE 1

| | | | | | | |
|---|---|---|---|---|---|---|
| Composition*: Mn₀.₀₅Mg₀.₉₅Al₂O₄ | Example 1 | Example 2 | Example 3 | Example 4 | Comparative Example 1 | Comparative Example 2 |
| Na content (mass ppm) | 15 | 45 | 110 | 14 | 1800 | 65 |
| Specific surface area (m²/g) | 0.13 | 0.78 | 4.2 | 0.12 | 0.67 | 4.4 |
| Firing temperature (°C) | 1350 | 1350 | 1350 | 1550 | 1350 | 1350 |
| Emission intensity | 100% | 60% | 41% | 120% | 37% | 29% |
| Evaluation | A | B | B | A | C | C |

* Composition of fluorescent material after firing in consideration of desorption of carbonic acid in manganese carbonate as carbon dioxide (CO₂) after firing

Table 1 shows that the fluorescent material containing a low content of sodium has excellent emission intensity (for example, Example 2 versus Comparative Example 1). Even in Example 3 (110 ppm by mass) in which the content of sodium is relatively high, the emission intensity of the fluorescent material is found to be improved by specifying the specific surface area in an appropriate range. Furthermore, the emission intensity of the fluorescent material prepared by increasing a firing temperature was further improved.

TABLE 2

| | | |
|---|---|---|
| Mn, Zn doping | Example 5 | Example 6 |
| Na content (mass ppm) | 14 | 12 |
| Specific surface area (m²/g) | 0.16 | 0.15 |
| Firing temperature (°C) | 1550 | 1550 |
| Emission intensity | 176% | 188% |
| Evaluation | AA | AA |

Table 2 shows that the emission intensity is further improved by doping an Mg—Al spinel type crystal with manganese and zinc.

### Reference Example 1

By compositing each of the fluorescent materials described in Examples 1 to 6 with a resin, putting the composite in a glass tube or the like, sealing the glass tube, and then disposing the glass tube between a blue light emitting diode as a light source and a light guide plate, a backlight capable of converting blue light of the blue light emitting diode into green light or red light is produced.

### Reference Example 2

A resin composition can be obtained by compositing each of the fluorescent materials described in Examples 1 to 6 with a resin and forming the composite into a sheet. A film obtained by sandwiching the resin composition between two barrier films, and sealing the films is placed on a light guide plate to produce a backlight capable of converting blue light with which the sheet is irradiated from a blue light emitting diode placed on an end surface (side surface) of the light guide plate through the light guide plate into green light or red light.

### Reference Example 3

By disposing each of the fluorescent materials described in Examples 1 to 6 in the vicinity of a light emitting part of a blue light emitting diode, a backlight capable of converting emitted blue light into green light or red light is produced.

### Reference Example 4

By mixing each of the fluorescent materials described in Examples 1 to 6 with a resist and then removing a solvent, a wavelength conversion material can be obtained. By disposing the obtained wavelength conversion material between a blue light emitting diode as a light source and a light guide plate or in a subsequent stage of an OLED as a light source, a backlight capable of converting blue light of the light source into green light or red light is produced.

### Reference Example 5

By mixing each of the fluorescent materials described in Examples 1 to 6 with conductive particles made of ZnS or the like to form a film, laminating an n-type transport layer on one side of the film, and laminating a p-type transport layer on the other side, an LED is obtained. Holes in a p-type semiconductor and electrons in an n-type semiconductor cancel out charges in a perovskite compound in a bonding surface when a current flows, and thereby the LED can emit light.

### Reference Example 6

By laminating a titanium oxide dense layer on the surface of a fluorine-doped tin oxide (FTO) substrate, laminating a porous aluminum oxide layer on the titanium oxide dense layer, laminating each of the fluorescent materials described in Examples 1 to 6 on the porous aluminum oxide layer, removing a solvent, then laminating a hole transport layer such as 2,2′,7,7′-tetrakis-(N,N′-di-p-methoxyphenylamine)-9,9′-spirobifluorene(Spiro-OMeTAD) on the fluorescent material, and laminating a silver (Ag) layer on the hole transport layer, a solar cell is prepared.

### Reference Example 7

By compositing each of the fluorescent materials described in Examples 1 to 6 with a resin, and molding the composite, the composition of the present embodiment can be obtained. By disposing the composition in a subsequent stage of a blue light emitting diode, laser diode illumination that converts blue light with which the composition is irradiated from the blue light emitting diode into green light or red light to emit white light is produced.

### Reference Example 8

By compositing each of the fluorescent materials described in Examples 1 to 6 with a resin and molding the composite, the composition of the present embodiment can be obtained. By using the obtained composition as a part of a photoelectric conversion layer, a photoelectric conversion element (photodetector) material included in a detection part that detects light is produced. The photoelectric conversion element material is used for an image detection part (image sensor) for a solid-state imaging device such as an X-ray imaging device or a CMOS image sensor, a detection part that detects predetermined features of a part of a living body, such as a fingerprint detection part, a face detection part, a vein detection part, and an iris detection part, and an optical biosensor such as a pulse oximeter.

### Reference Example 9

By compositing each of the fluorescent materials described in Examples 1 to 6 with a resin and molding the composite, the composition of the present embodiment can be obtained. The obtained composition can be used as a film for improving the light conversion efficiency of a solar cell. The form of the conversion efficiency improvement sheet is not particularly limited, and the conversion efficiency improvement sheet is used by being applied to a base material. The base material is not particularly limited as long as it has high transparency. For example, a PET film or a moth-eye film or the like is desirable. The solar cell using a solar cell conversion efficiency improvement sheet is not particularly limited, and the conversion efficiency improvement sheet has a conversion function from a wavelength region where the sensitivity of the solar cell is low to a wavelength region where the sensitivity is high.

### Reference Example 10

By compositing each of the fluorescent materials described in Examples 1 to 6 with a resin and molding the composite, the composition of the present embodiment can be obtained. The obtained composition can be used as a light source for single photon generation such as a quantum computer, quantum teleportation, and quantum cryptographic communication.

1. A fluorescent material having a core-shell structure including a core part and a shell part,
the core part composed of a crystal phase of an inorganic compound having an elemental composition represented by Formula: 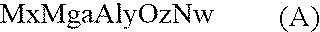
wherein: M represents at least one metal element selected from the group consisting of manganese, strontium, cerium, praseodymium, neodymium, samarium, europium, gadolinium, terbium, dysprosium, thulium, zinc, and ytterbium; × satisfies 0.001 ≤ × ≤ 0.3; a satisfies 0 ≤ a ≤ 1.0 - ×; y satisfies 1.2 ≤ y ≤ 11.3; z satisfies 2.8 ≤ z ≤ 18; and w satisfies 0 ≤ w ≤ 1.0,
the shell part formed on at least a part of a surface of the core part and containing at least one element selected from the group consisting of boron and silicon, wherein:
the core part has a sodium content of 1700 ppm by mass or less and a specific surface area of 0.01 to 4.30 m²/g; and
a ratio Y/X of a peak area value Y of boron or silicon to a peak area value X of the metal element M present in the shell part satisfies 0 < Y/X ≤ 0.095 when EDX measurement of a cross section of the fluorescent material is performed.

2. A fluorescent material represented by Formula: 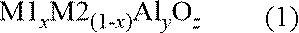
wherein: M1 and M2 represent one or more different metal elements; × satisfies 0.001 ≤ × ≤ 0.3; y satisfies 1.2 ≤ y ≤ 11.3; and z satisfies 2.8 ≤ z ≤ 18,
the fluorescent material having a sodium content of 1700 ppm by mass or less and a specific surface area of 0.01 to 4.30 m²/g.

3. The fluorescent material according to claim 2, wherein the fluorescent material has a spinel-type crystal structure.

4. The fluorescent material according to claim 2, wherein the M1 is at least one metal element selected from the group consisting of manganese, cerium, praseodymium, neodymium, samarium, europium, gadolinium, terbium, dysprosium, thulium, and ytterbium, and the M2 is magnesium.

5. A fluorescent material represented by Formula: 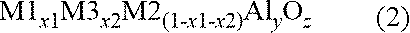
wherein: M1, M2, and M3 represent one or more different metal elements; ×1 and ×2 satisfy 0.12 ≤ ×1 + ×2 ≤ 0.14, and 1.4 ≤ ×1/×2 ≤ 1.8; y satisfies y = 2; and z satisfies z = 4,
the fluorescent material having a sodium content of 1700 ppm by mass or less and a specific surface area of 0.01 to 4.30 m²/g.

6. The fluorescent material according to claim 5, wherein the M1 is at least one metal element selected from the group consisting of manganese, cerium, praseodymium, neodymium, samarium, europium, gadolinium, terbium, dysprosium, thulium, and ytterbium; the M2 is magnesium; and the M3 is at least one metal element selected from the group consisting of zinc, cerium, praseodymium, neodymium, samarium, europium, gadolinium, terbium, dysprosium, thulium, and ytterbium.

7. A film comprising the fluorescent material according to claim 1.

8. A light emitting element comprising the fluorescent material according to claim 1.

9. A light emitting device comprising the light emitting element according to claim 8.

10. A display comprising the light emitting element according to claim 8.

11. A phosphor wheel comprising the fluorescent material according to claim 1.

12. A projector comprising the phosphor wheel according to claim 11.

13. A method for producing a fluorescent material represented by Formula: 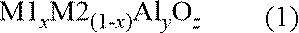
wherein: M1 and M2 represent one or more different metal elements; × satisfies 0.001 ≤ × ≤ 0.3; y satisfies 1.2 ≤ y ≤ 11.3; and z satisfies 2.8 ≤ z ≤ 18,
the method comprising the step of firing a raw material obtained by mixing an M1 compound which is a raw material of the M1 element, an M2 compound which is a raw material of the M2 element, and an Al compound which is a raw material of the Al element, wherein:
the Al compound has a purity of 99.9% by mass or more and a specific surface area of 0.01 to 5.0 m²/g; and
the firing step is performed at a temperature of 1250 to 1700° C.
